(19) United States
(12) Patent Application Publication
(10) Pub. No.: US 2026/0031786 A1
(43) Pub. Date: Jan. 29, 2026

(54) Edge Treatment for Spurious Mode Suppression in Thin-Film LiNbO3

(71) Applicants: UNM Rainforest Innovations, Albuquerque, NM (US); National Technology & Engineering Solutions of Sandia, LLC, Albuquerque, NM (US)

(72) Inventors: Tito Busani, Albuquerque, NM (US); Aleem Siddiqui, Albuquerque, NM (US); Arjun Aryal, Albuquerque, NM (US); Sidhant Tiwari, Albuquerque, NM (US)

(73) Assignees: UNM Rainforest Innovations, Albuquerque, NM (US); National Technology & Engineering Solutions of Sandia, LLC, Albuquerque, NM (US)

(21) Appl. No.: 19/282,992

(22) Filed: Jul. 28, 2025

Related U.S. Application Data
(60) Provisional application No. 63/676,317, filed on Jul. 26, 2024.

(51) Int. Cl. H03H 9/17; H03H 3/02

(52) U.S. Cl. CPC H03H 9/171; H03H 3/02; H03H 9/176

(57) ABSTRACT

A lithium niobate resonator having a sidewall with features configured to scatter spurious acoustic modes, and methods of making the same using edge treatment processes that introduce controlled roughness to suppress undesired resonances across a broad frequency range.

### RELATED APPLICATIONS

This application claims priority to U.S. Provisional Application No. 63/676,317, filed on Jul. 26, 2024, which is incorporated herein in its entirety.

### STATEMENT REGARDING FEDERALLY SPONSORED RESEARCH & DEVELOPMENT

This invention was made with government support by the DOE grant No. DOE-NA0003525. The government has certain rights in the invention.

### INCORPORATION BY REFERENCE OF MATERIAL SUBMITTED ON A COMPACT DISC

Not applicable.

### BACKGROUND OF THE INVENTION

Thin-film lithium niobate is an attractive material for RF acoustic devices because of its high electromechanical coupling. However, due to the large coupling and the high anisotropy, thin-film lithium niobate resonators are prone to accidental resonances called spurious modes. These modes compromise the frequency response of the resonators, limiting their use in filter and oscillator applications.

Moreover, piezoelectric resonators are key components in modern day electronics. Originally developed as high-stability frequency references for AM radio stations in the 1920s, piezoelectric resonators now have applications as sensors, filters, clocks, and ultrasonic transducers. By leveraging the piezoelectric effect, these devices convert applied voltages to strains (FIGS. 1a-b). In the case of an alternating voltage, acoustic waves are generated. These acoustic waves reflect off the boundaries of the device, causing resonance when the reflected waves constructively interfere with the original waves. The specific resonance mode and frequency depends on the geometry of the device. For example, frequencies of bulk acoustic wave (BAW) resonators typically are set by their thickness, contour and Lame mode resonators by their width, and Lamb and surface acoustic wave (SAW) resonators by their electrode pitch. Acoustic wave-based resonators are significantly more compact than their electromagnetic equivalents at the same frequency. This size advantage has made them useful in applications like mobile phone filters and it has motivated the development of thin-film piezoelectric devices, where the coupling between voltage and strain is notably strong. High electromechanical coupling factor and high-quality factor (Q factor) are necessary for optimal piezoelectric filter performance (FIG. 2a,b). Several design techniques have been proposed for coupling factor and Q factor enhancement in piezoelectric resonators, but the best these techniques can do is approach the material limits. For this reason, much of the recent work on 5G compatible piezoelectric resonators has been focused on ion-sliced thin-film single-crystal lithium niobate (Table 1).

TABLE1
State-Of-The-Art kₜ² and Q performance for Thin-Film
Lithium Niobate MEMS or Acoustic Resonators

| | Thickness | | | | | | |
|---|---|---|---|---|---|---|---|
| | of LN | | f | | | f * Q | |
| Material | film (nm) | Mode | (GHz) | k²(%) | Q | ( . . . *e12) | Reference |
| Y-cut | 1200 | A1 | 1.70 | 6.30 | 5341 | 9.079 | {Yang, 2018} [37] |
| Z-cut | 400 | A1 | 4.50 | 24.00 | 118 | 0.531 | {Yang, 2018} [37] |
| Z-cut | 400 | A3 | 12.90 | 3.70 | 224 | 2.890 | {Yang, 2018} [37] |
| Z-cut | 400 | A5 | 21.40 | 1.50 | 287 | 6.141 | {Yang, 2018} [37] |
| Z-cut | 400 | A7 | 29.90 | 0.95 | 328 | 9.807 | {Yang, 2018} [37] |
| Y-cut | 1200 | A1 | 1.65 | 14.00 | 3112 | 5.135 | {Yang, 2020} [28] |
| X-cut | 2000 | S0 | 0.05 | 27.80 | 5329 | 0.266 | {Colombo, 2020} [38] |
| 128Y-cut | 550 | A1 | 3.20 | 46.40 | 598 | 1.913 | {Lu, 2020} [39] |
| 128Y-cut | 550 | A3 | 9.55 | 5.66 | 359 | 3.428 | {Lu, 2020} [39] |
| 128Y-cut | 550 | A5 | 15.90 | 2.26 | 321 | 5.202 | {Lu, 2020} [39] |
| 128Y-cut | 550 | A7 | 22.20 | 1.14 | 294 | 6.526 | {Lu, 2020} [39] |
| Z-cut | 400 | A1 | 4.40 | 15.00 | 50 | 0.220 | {Kourani, 2020} [40] |
| Z-cut | 400 | A3 | 12.90 | 1.90 | 360 | 4.644 | {Kourani, 2020} [40] |
| Z-cut | 400 | A5 | 21.60 | 1.00 | 520 | 11.232 | {Kourani, 2020} [40] |
| Z-cut | 400 | A7 | 30.10 | 0.72 | 670 | 20.167 | {Kourani, 2020} [40] |
| Z-cut | 400 | A9 | 38.70 | 0.63 | 570 | 22.059 | {Kourani, 2020} [40] |
| Z-cut | 400 | A3 | 13.00 | 3.80 | 372 | 4.836 | {Yang, 2020} [40] |
| Z-cut | 400 | A5 | 21.60 | 1.20 | 566 | 12.220 | {Yang, 2020} [40] |
| Z-cut | 400 | A7 | 30.20 | 6.30 | 715 | 21.590 | {Yang, 2020} [41] |
| Z-cut | 400 | A9 | 38.80 | 14.00 | 539 | 20.910 | {Yang, 2020} [41] |
| Z-cut | 400 | A11 | 47.40 | 24.00 | 474 | 22.460 | {Yang, 2020} [41] |
| Z-cut | 400 | A13 | 55.00 | 3.70 | 340 | 18.700 | {Yang, 2020} [41] |

Our Work

| | | | | | | | |
|---|---|---|---|---|---|---|---|
| Y-cut | 2000 | SH0 | 0.103 | 10.9 | 37.1 | 0.004 | smooth sidewall |
| | | | | 10.8 | 82.6 | 0.009 | rough sidewall |
| Y-cut | 2000 | SH0 | 0.206 | 15.6 | 1468.5 | 0.302 | smooth sidewall |
| | | | | 15.0 | 1239.9 | 0.277 | rough sidewall |
| Y-cut | 2000 | SH0 | 0.319 | 1.1 | 2279.2 | 0.727 | smooth sidewall |
| | | | | 1.0 | 540.3 | 0.187 | rough sidewall |
| Y-cut | 2000 | A1 | 0.779 | 3.7 | 1557.5 | 1.213 | smooth sidewall |
| | | | | 7.2 | 123.5 | 0.094 | rough sidewall |
| Y-cut | 2000 | A1 | 0.837 | 3.0 | 3486.0 | 2.917 | smooth sidewall |
| | | | | 3.9 | 660.5 | 0.541 | rough sidewall |
| Y-cut | 2000 | A1 | 0.864 | 3.5 | 1394.3 | 1.205 | smooth sidewall |
| | | | | 2.2 | 1067.6 | 0.912 | rough sidewall |

Due to being single crystalline, the Q factors of lithium niobate exceed that of the polycrystalline piezoelectric thin films, with Q factors of up to 30,000 demonstrated in bulk crystals. Lithium niobate is among the highest coupling factors of all piezoelectric resonators, with resonators having demonstrated coupling coefficients in excess of 40%. One of the major challenges in the adoption of thin-film lithium niobate piezoelectric resonators is that of spurious resonant modes. Due to the high anisotropy, the high coupling, and the low losses of lithium niobate, resonances outside of the target mode are easy to excite. When these resonances are near the target mode, they introduce numerous spikes into the filter transfer function (FIG. 2c,d), which either complicate or degrade filter performance. Several methods to mitigate spurious mode in thin-film lithium niobate have been investigated, such as anchor shaping, acoustic reflectors, electrode optimization and device arraying. Thus, designing robust filters for ultrahigh frequency (UHF) and very high frequency (VHF) bands continues to remain challenging, highlighting the need for alternative design approaches to overcome the limitations present in the RF spectrum, including UHF, VHF, and 5G.

### SUMMARY OF THE INVENTION

In one embodiment, the present invention concerns a novel method of spurious mode suppression through a special edge treatment etch process involving thin-film lithium niobate resonators fabricated having rough sidewalls.

In another embodiment, the present invention concerns edge-treated resonators which show a weaker spurious mode response used to mitigate spurious resonances, a major issue in lithium niobate Lamb wave devices.

In another embodiment, the present invention concerns resonators that operate effectively in the UHF/VHF range, and which can be scaled up to 18.5 GHz and beyond.

In another embodiment, the present invention concerns novel fabrication processes that achieve resonator designs that operate effectively in the UHF/VHF range, and which can be scaled up to 18.5 GHz and beyond

In another embodiment, the present invention concerns novel methods to mitigate spurious modes through fabrication processes designed to optimize the device geometry.

In another embodiment, the present invention concerns thin-film lithium niobate resonators fabricated using a high-aspect-ratio lithium niobate dry etching process wherein the free edges of the resonators are subsequently treated with a targeted etch process to enhance the wave scattering.

In another embodiment, the present invention concerns edge treatment processes that influence the spurious mode response of thin-film lithium niobate resonators. Two thin-film lithium niobate resonators were fabricated, one with “smooth sidewalls” and one with “roughened sidewalls”, and their frequency response was characterized. It was found that introducing edge roughness reduced the spurious modes with minimal influence on the main mode. Because spurious modes are relatively short in wavelength and are more easily scattered by the rough edges, they prevent the modes from forming a strong resonance.

In another embodiment, the present invention concerns a lithium niobate resonator having a sidewall with features configured to scatter spurious acoustic modes, and methods of making the same using edge treatment processes that introduce controlled roughness to suppress undesired resonances across a broad frequency range.

Additional objects and advantages of the invention will be set forth in part in the description which follows, and in part will be obvious from the description, or may be learned by practice of the invention. The objects and advantages of the invention will be realized and attained by means of the elements and combinations particularly pointed out in the appended claims.

### BRIEF DESCRIPTION OF THE SEVERAL VIEWS OF THE DRAWINGS

In the drawings, which are not necessarily drawn to scale, like numerals may describe substantially similar components throughout the several views. Like numerals having different letter suffixes may represent different instances of substantially similar components. The drawings illustrate generally, by way of example, but not by way of limitation, a detailed description of certain embodiments discussed in the present document.

FIG. 1A. An oscillating voltage is applied to a piezoelectric slab, generating acoustic waves that propagate away from the electrodes.

FIG. 1B. When the frequency of the voltage matches that of the slab mechanical resonance mode, the generated acoustic waves constructively interfere with previously generated acoustic waves that were reflected off the boundaries and mechanical resonance is excited.

FIG. 2A. Admittances of series (red) and shunt (blue) elements of a piezoelectric filter as a function of frequency. The electromechanical coupling factor determines the separation of the high admittance point (fs) and the low admittance point (fp), with a higher coupling factor increasing the separation. A higher Q factor makes the transition between fs and fp more abrupt.

FIG. 2B. Ideal filter response. A higher electromechanical coupling increases the bandwidth of the filter, and a higher Q factor increases the sharpness of the filter passband.

FIG. 2C Influence of spurious modes on piezoelectric resonator admittance, where additional modes are superimposed over the expected resonator response.

FIG. 2D Influence of spurious modes on filter response.

FIG. 3A. Diagram of lithium niobate (LN) resonator design.

FIG. 3B Microscope image of a fabricated device.

FIG. 3C Device fabrication process flow.

FIG. 4A Top view of a typical etched structure using CHF3/Ar plasma.

FIG. 4B Side view of the etched structure using Ti/Al/Cr as hard mask and

FIG. 4C using Ti/Al mask as hard mask.

FIG. 5A. Measured admittance magnitudes for fabricated thin-film lithium niobate resonators. Full frequency sweep of measured devices.

FIG. 5B. Measured admittance magnitudes for fabricated thin-film lithium niobate resonators. Lower frequency modes from 300 kHz to 400 MHZ.

FIG. 5C. Measured admittance magnitudes for fabricated thin-film lithium niobate resonators. Lower frequency modes from 700 MHz to 1 GHz.

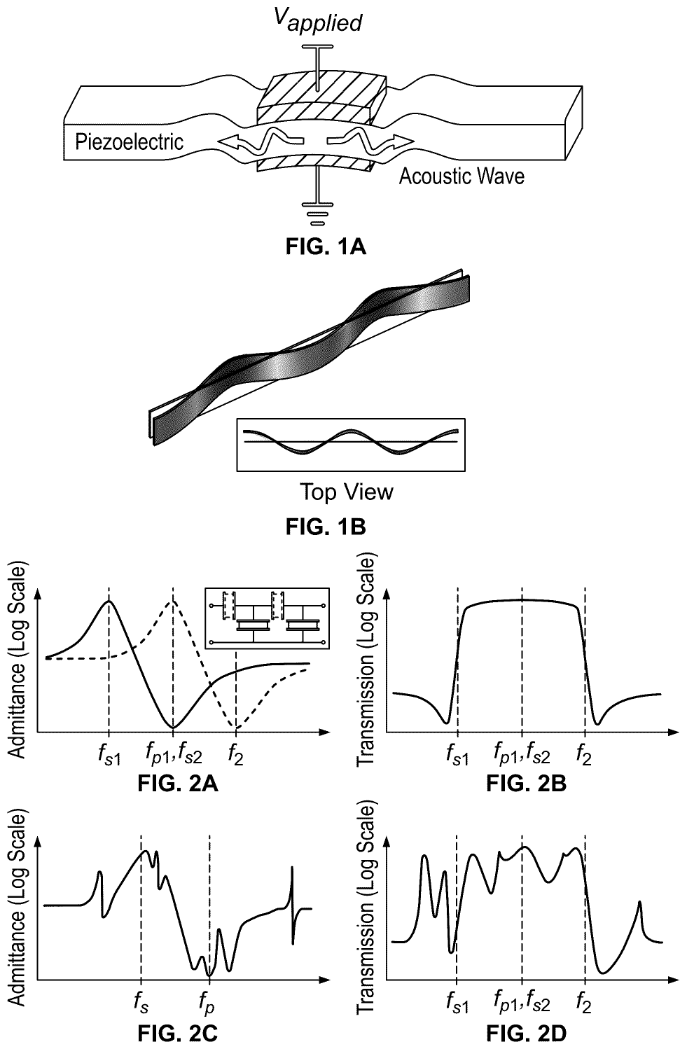

### DESCRIPTION OF THE INVENTION

Detailed embodiments of the present invention are disclosed herein; however, it is to be understood that the disclosed embodiments are merely exemplary of the invention, which may be embodied in various forms. Therefore, specific structural and functional details disclosed herein are not to be interpreted as limiting, but merely as a representative basis for teaching one skilled in the art to variously employ the present invention in virtually any appropriately detailed method, structure, or system. Further, the terms and phrases used herein are not intended to be limiting, but rather to provide an understandable description of the invention.

In one embodiment, the present invention concerns thin-film lithium niobate resonators designed to provide additional wave scattering that disrupts spurious modes, preventing them from forming strong resonances and resulting in a smoother resonator frequency response. The effectiveness of the present invention is demonstrated by ability of suppressing spurious or reducing the intensity of modes up to 18.5 GHZ. This is a particularly counter-intuitive result as smooth, high-aspect ratio sidewalls are typically expected to give the best device performance. We evaluate anticipating significant potential as we continue to refine and scale this methodology, for integration into the 5G frequency range.

### Device Fabrication and Edge Treatment Process

A nominal design for a resonator was established as a baseline, upon which the embodiments of the present invention's fabrication process was used to enhance performance characteristics. This foundational design served as a control to rigorously evaluate the impact of the present invention's novel approaches, ensuring that any observed improvements could be directly attributed to the specific fabrication modifications applied.

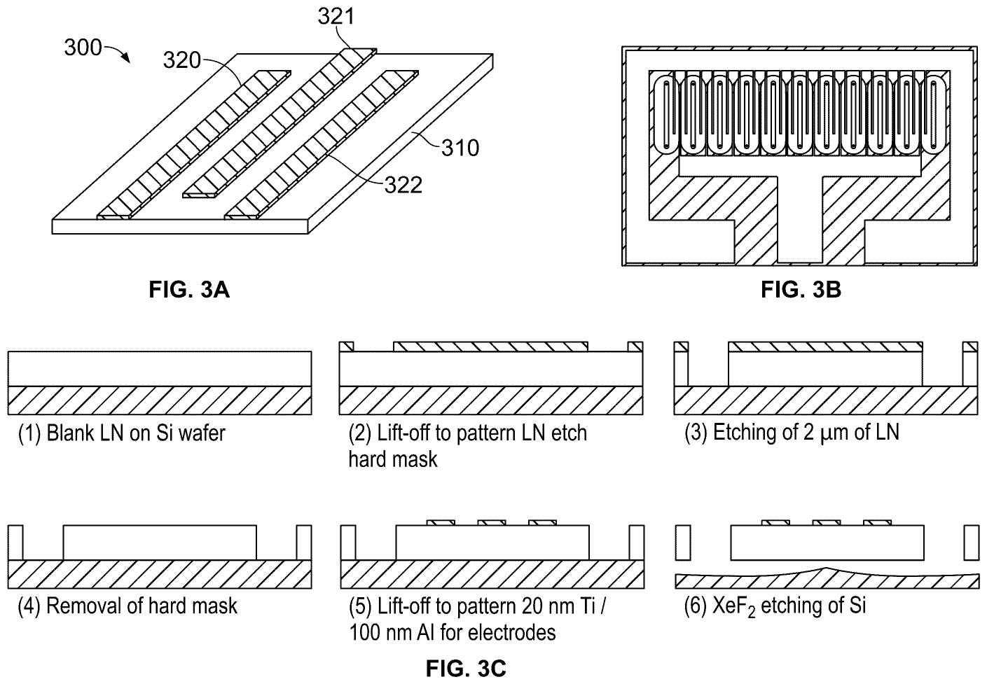

A schematic of the designed resonator 300 is shown in FIG. 3a. The device is a center-symmetric three finger Lamb wave resonator on Y-cut lithium niobate 310, with the electrode fingers 320-322 perpendicular to the lithium niobate X-axis, and the finger widths and the finger gaps are both ⅛th of the plate width. Several resonator elements are cascaded in parallel to increase the total device admittance.

An image of a fabricated device is shown in FIG. 3b. Two sets of Lamb wave resonator devices were fabricated for comparison: one with high quality “smooth sidewalls”, and another with a “rough sidewall” that was exposed to an etch treatment. FIG. 3c shows the fabrication process for the device, wherein a 2 μm Y-cut lithium niobate thin-film on Si substrate was first immersed in piranha solution (H2SO4:H202, 4:1) for 10 min, then immediately exposed to H2 plasma. The H2 plasma was used to improve the adhesion between the LN film surface and the deposited metal hard mask used for the etching process. A negative photoresist (AZ nLOF 2035) mask was prepared for lift-off patterning of the metal hard mask. Patterned samples were cleaned by immersion into HCl:H2O, 1:3 ratio, before metal deposition. A Ti/Al/Cr hard mask was then deposited, using an e-beam evaporator at a pressure of 1.0×−10-6 Torr. After lift-off, the samples were then etched using a Plasma-Therm Inductively Coupled Plasma (ICP) using CHF3/Ar as precursor gases.

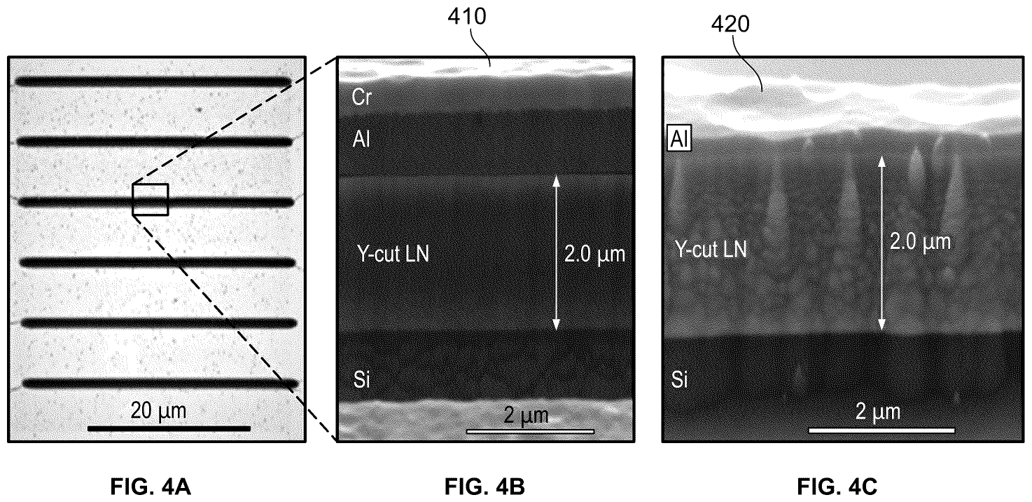

A top view of the etched structures of the Lamb wave resonators is shown in FIG. 4a. The resulting smooth side wall 410 is shown in FIG. 4b. Using a Ti/Al hard mask rather than Ti/Al/Cr, and applying the etching recipe that was used previously, the embodiments of the present were able to produce rough sidewall surfaces 420 as shown in FIG. 4c.

Al reacts with the fluorine process much faster than the Cr resulting in a poor-quality sidewall etch. After the dry etching, the hard mask was removed using standard Cr etchant and 6.25% HF diluted in H2O respectively for the Cr and the Ti/Al. Next, 20 nm/100 nm of Ti/Al was deposited as the device electrode metal, using an electron bean evaporator at˜-10-6 Torr partial pressure. The devices were then released using XeF2 dry vapor to etch partially the Si underneath the resonator body. The comparison of FIG. 4b,c illustrates that the present invention achieved the desired roughened edges.

Thus, as shown, smooth sidewall 410 lacks surface irregularities while roughened sidewall 420 has surface irregularities on it. Surface irregularities are formed when the aluminum in the mask reacts with fluorine to form irregular etch fronts producing sidewall roughness.

### Characterization Results

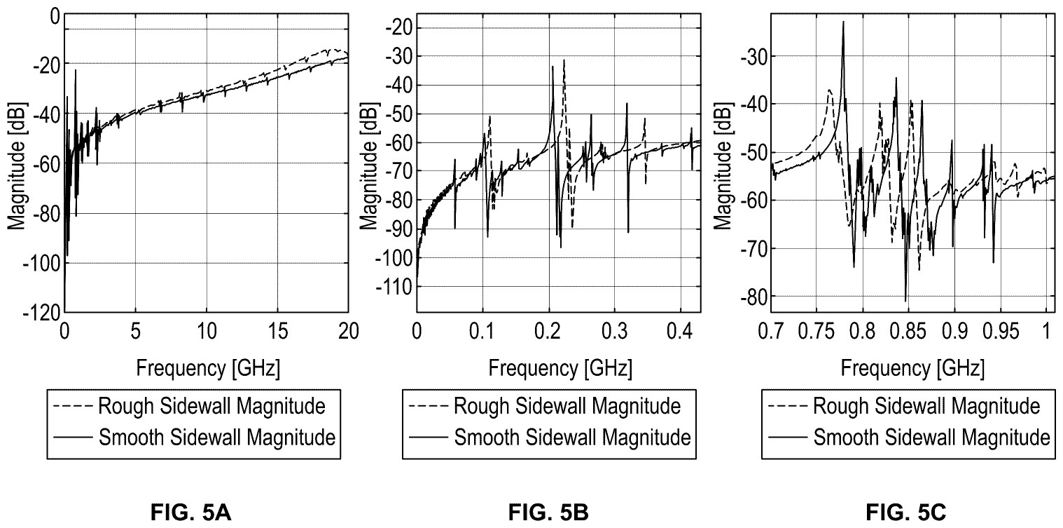

The fabricated devices were tested and characterized at room temperature using a Keysight P9374A network analyzer after performing a Short-Open-Load-Through (SOLT) calibration of the Ground-Signal-Ground (GSG) probes (GGB Industries, Model 40A). Measurements were acquired over the full range of the network analyzer, 300 kHz to 20 GHz. The result shown in FIG. 5a compares the response of devices with smooth sidewalls and devices with side walls roughened by the edge treatment.

The investigation was able to excite multiple resonances corresponding to acoustic modes supported by the device, and the highest resonant frequency that could measure with set up used was found to be 18.5 GHZ. The investigation observed that the resonant frequencies of all the target modes are all slightly shifted between the two devices. This can be either due to die-to-die process variations or the fact that the edge treatment not only roughens the edge but removes the material, perturbing the resonator geometry. FIG. 5b,c show the resonant modes of interest for this work. The modes in FIG. 5b (103 MHZ, 206 MHZ, and 319 MHz) are identified to be shear horizontal (SHO) modes and the modes in FIG. 5c (779 MHZ, 837 MHz, and 864 MHz) are identified to be first-order antisymmetric (A1) modes. The smooth sidewall devices, shown as solid lines, are riddled with several weaker spurious modes throughout the frequency range. The roughened sidewall devices, shown as dashes, show a smoother frequency response. In the low frequency range (FIG. 5b), several spurious modes, respectively at 50 MHz, 150 MHz, and 365 MHZ are completely removed by the edge treatment process, while the peaks at 175 MHz and 250 MHz are greatly suppressed. Those peaks are marked with an arrow in FIG. 5b. The magnitude of the strongest resonance near 200 MHz is barely changed by the edge treatment. As stated earlier, this is a counterintuitive result as edge roughening is typically not seen as a way to improve resonator performance.

It is believed that the spurious modes in the 100 to 300 MHz have shorter wavelengths than the main 200 MHz mode and are thus much more easily scattered by the small features introduced by the edge roughening. In contrast, all modes in the 700 MHz to 1 GHz range (FIG. 5c) are degraded due to the edge roughening with only the three strongest modes (approximately 760 MHZ, 820 MHz, and 850 MHZ) remaining after the edge treatment. This is consistent with the hypothesis that the edge roughening more strongly affects smaller wavelength modes. For example, the scattering loss as due to Rayleigh scattering is estimated as:

αₛ=(4πσ/λ)² (1)
where σ is the root mean square (RMS) surface roughness and λ is the wavelength of the wave. Thus, since the 750-850 MHz modes have a shorter wavelength than the 200 MHz mode, the edge roughening would be expected to have larger impact on these higher frequency modes. Multiple resonators were fabricated on the same chip to observe for any statistical variation in the rejection of spurious modes.

The measured peak admittance of the fundamental mode for the device with smooth side was at 200 MHz is consistent with the response simulated in COMSOL Multiphysics which was found to be at 178 MHz. The Q factor for the main resonance modes is estimated by measuring the 3 dB bandwidth of the series resonances and using Eq. (2), as was done in. The electromechanical coupling factors, k²ₜ, were calculated using Eq. (3). These results are summarized in Table 1 and compared to the state-of-the-art results found in literature for different LN acoustic wave resonators for different crystallographic orientation.

$$Q = \frac{Δ {f}_{3 dB}}{{f}_{s}} \qquad ( 2 )$$

$$and$$

$${k}_{t}^{2} = \frac{{π}^{2}}{8} \frac{{f}_{p}^{2} - {f}_{s}^{2}}{{f}_{s}^{2}} \qquad ( 3 )$$

where fs,p=series or parallel resonant frequency of a piezoelectric resonator, and f3 dB=the bandwidth between the points where the admittance amplitude has decreased by 3 dB relative to the series resonance admittance peak. It should be noted that the presence of spurious modes distorts the resonance mode's admittance profile, making accurate estimation of Q and k²ₜ difficult. In Table 1 we summarized the state-of-the-art k²ₜ and Q and for several LN cuts and compared them to the devices fabricated by the present invention's fabrication process for both rough and smooth side walls. The values k²ₜ were found to not differ significantly between the rough and smooth sidewall devices. In contrast, the Q factor for several of the modes is found to have been severely degraded by the edge treatment. This is expected, as the roughened sidewalls to scatter acoustic waves. However, the main resonant mode at 206 MHz was found to not be significantly affected, maintaining a high Q factor.

### CONCLUSION

In this work we present a study on how an edge treatment process influences the spurious mode response of thin-film lithium niobate resonators. Two thin-film lithium niobate resonators are fabricated, one with “smooth sidewalls” and one with “roughened sidewalls”, and their frequency response is characterized. It was found that introducing edge roughness reduced the spurious modes with minimal influence on the main mode. The hypothesis is that the spurious modes are relatively short in wavelength and are more easily scattered by the rough edges, thus preventing the modes from forming a strong resonance. More test structures with controlled roughness need to be fabricated to validate this idea over a wide range of resonances and device architectures. However, this research potentially shows a new method for mitigating spurious mode in Lamb wave resonators, a major challenge that must be resolved for the practical realization of thin-film lithium niobate RF devices for 5G applications.

While the foregoing written description enables one of ordinary skill to make and use what is considered presently to be the best mode thereof, those of ordinary skill will understand and appreciate the existence of variations, combinations, and equivalents of the specific embodiment, method, and examples herein. The disclosure should therefore not be limited by the above-described embodiments, methods, and examples, but by all embodiments and methods within the scope and spirit of the disclosure.

What is claimed is:

1. A method of reducing spurious mode suppression in lithium niobate resonators comprising the steps of:
i. fabricating a thin-film lithium niobate resonator having rough sidewalls;
ii. applying an edge treatment process to form roughened sidewalls, wherein the sidewall roughness is configured to scatter spurious acoustic wave modes and reduce their resonant amplitude.

2. The method of claim 1, wherein the spurious acoustic wave modes are within a tunable frequency range determined by the degree of sidewall roughness.

3. The method of claim 1, wherein said spurious modes include but are not limited to modes in the range of 100 MHz to 20 GHz.

4. The method of claim 1, wherein said roughness features are configured to scatter spurious acoustic wave modes across a wide frequency range.

5. The method of claim 1, wherein the roughness profile of said sidewalls is selected based on a desired scattering response for a specific frequency or frequency band.

6. The method of claim 4, wherein the roughness profile is controlled by the composition of the hard mask and the parameters of a fluorine-based dry etch process.

7. The method of claim 1, wherein said edge treatment comprises:
i. using a Ti/Al hard mask in combination with a CHF₃/Ar plasma etching process,
ii, wherein the aluminum in the mask reacts with fluorine to form irregular etch fronts producing sidewall roughness.

8. The method of claim 1, wherein said roughness of the resonator sidewalls scatter spurious modes across a range of frequency bands.

9. The method of claim 1, wherein said roughness of the resonator sidewalls scatter spurious modes across Very High Frequency (VHF) bands.

10. The method of claim 1, wherein said roughness of the resonator sidewalls scatter spurious modes across Super High Frequency (SHF) bands.

11. The method of claim 1, wherein said roughness of the resonator sidewalls scatter spurious modes across Ultra High Frequency (UHF) bands.

12. A method of reducing spurious mode suppression in lithium niobate resonators comprising the steps of:
i. fabricating a thin-film lithium niobate resonator having rough sidewalls wherein said rough sidewalls lack smooth surfaces but have surface irregularities;
ii. applying an edge treatment process to form said roughened sidewalls, wherein said sidewall roughness is configured to scatter spurious acoustic wave modes and reduce their resonant amplitude.

13. The method of claim 12, wherein spurious acoustic wave modes are within a tunable frequency range determined by the degree of sidewall roughness.

14. The method of claim 12, wherein said spurious modes include but are not limited to modes in the range of 100 MHz to 20 GHZ.

15. The method of claim 12, wherein said roughness features are configured to scatter spurious acoustic wave modes across a wide frequency range.

16. The method of claim 12, wherein the roughness profile of said sidewalls is selected based on a desired scattering response for a specific frequency or frequency band.

17. The method of claim 16, wherein the roughness profile is controlled by the composition of the hard mask and the parameters of a fluorine-based dry etch process.

18. The method of claim 12, wherein said edge treatment comprises:
i. using a Ti/Al hard mask in combination with a CHF₃/Ar plasma etching process,
ii. wherein the aluminum in the mask reacts with fluorine to form irregular etch fronts producing sidewall roughness.

19. A lithium niobate resonator comprising: at least one sidewall, said at least one side wall having sidewall features wherein spurious modes across a range of frequency bands are scattered by said sidewall features.

20. The lithium niobate resonator of claim 19 wherein said sidewall features are surface irregularities.

21. The lithium niobate resonator of claim 19 wherein said sidewall features are surface irregularities that do not produce a smooth surface.
